(19) United States
(12) Patent Application Publication
(10) Pub. No.: US 2026/0234313 A1
(43) Pub. Date: Aug. 13, 2026

(54) ADHESIVE FILM, OPTICAL MEMBER, AND OPTICAL DISPLAY APPARATUS

(71) Applicant: SAMSUNG SDI CO., LTD., Yongin-si, Gyeonggi-do (KR)

(72) Inventors: Jung Hyo LEE, Suwon-si (KR); Won KIM, Suwon-si (KR); Young Hoon KIM, Suwon-si (KR); Ji Hye LEE, Suwon-si (KR); Il Jin KIM, Suwon-si (KR)

(21) Appl. No.: 19/471,553

(22) PCT Filed: Apr. 4, 2024
(86) PCT No.: PCT/KR2024/004432

§ 371 Date: Oct. 1, 2025

(30) Foreign Application Priority Data
Apr. 7, 2023 (KR) 10-2023-0046278

(51) Int. Cl. C08F 265/06; C09J 7/38; H10K 59/80; H10K 77/10; H10K 102/00

(52) U.S. Cl. CPC C08F 265/06; C09J 7/385; H10K 59/871; H10K 77/111; C09J 2301/312; H10K 2102/311

(57) ABSTRACT

Provided are an adhesive film, an optical member comprising same, and an optical display apparatus comprising same, the adhesive film comprising a thermally cured product of an adhesive composition comprising a (meth)acrylic copolymer, a curing agent, an at least monofunctional compound containing an aromatic group, an at least monofunctional compound containing a long-chain alkyl group, and an initiator, wherein the adhesive film has a variation of peel strength of formula 1 of at most 1.0 before light radiation.

### TECHNICAL FIELD

The present invention relates to an adhesive film, an optical member, and an optical display apparatus.

### BACKGROUND ART

Recently, the development of optical display apparatuses based on organic light-emitting diodes (OLEDs) is underway. Particularly, optical display apparatuses based on organic light-emitting diodes having flexibility have attracted attention.

Flexible panels based on organic light-emitting diodes having flexibility include plastic films such as polyimide-based films on the top and bottom of the panel. The flexible panel is relatively flexible compared to liquid crystal panels and typical organic light-emitting diodes-based panels. For this reason, scratches may occur on the surface of the flexible panel during a process such as processing, assembling, and/or inspecting the flexible panel, and thus a processing protective film for protecting the panel needs to be temporarily attached to the flexible panel. In the inspection of the flexible panel, when there are defects such as an abnormal appearance or foreign matter, the processing protective film is required to have low peel strength so that it can be easily peeled off of the flexible panel. After the inspection of the flexible panel, a reinforcing protective film needs to be permanently attached to the panel to support the panel and protect the panel from the external environment. Therefore, it may be preferable that the reinforcing protective film has high peel strength and reliability compared to the processing protective film.

However, a conventional panel manufacturing process is complicated because sequential processes of laminating a temporary processing protective film on a panel, peeling the temporary processing protective film off of the panel, and laminating a reinforcing protective film on the panel are all required. Also, since the processing protective film must be discarded after the peeling process, there is a problem that economic efficiency and environmental friendliness are degraded.

The background art of the present invention is disclosed in Japanese Registered Patent No. 5683369 and the like.

### DISCLOSURE

### Technical Problem

The present invention is directed to providing an adhesive protective film which can be easily removed after being adhered to an optical element and can be fixed to an optical element with high reliability through a predetermined process.

The present invention is also directed to providing an adhesive protective film which can be easily removed from an optical element due to having a low peel strength increase rate even after being adhered to the optical element for a long period of time.

The present invention is also directed to providing an adhesive protective film which is adhered to an optical element with low peel strength to temporarily protect the optical element before light irradiation and is easily removed from the optical element without any deformation and/or damage to the optical element by selectively cutting only the unnecessary part.

The present invention is also directed to providing an adhesive protective film which can be fixed to an optical element to increase the durability of the optical element due to having significantly high peel strength after light irradiation and thermal treatment compared to before light irradiation.

### Technical Solution

One aspect of the present invention provides an adhesive film.

The adhesive film includes a thermally cured product of an adhesive composition including a (meth)acrylic based copolymer, a curing agent, an aromatic group-containing monofunctional or higher compound, a long-chain alkyl group-containing monofunctional or higher compound, and an initiator, and the adhesive film has a peel strength increase rate of 1.0 or less as measured by the following Equation 1 before light irradiation:

$$Peel strength increase rate = ( P 2 - P 1 ) / P 1 \qquad [ Equation 1 ]$$

(in Equation 1,
P1 is the peel strength (units: gf/inch) of the adhesive film with respect to an adherend after a specimen prepared by adhering the adhesive film to the adherend is allowed to stand at 25° C. and a relative humidity of 50% for 30 minutes, and
P2 is the peel strength (units: gf/inch) of the adhesive film with respect to an adherend after a specimen prepared by adhering the adhesive film to the adherend is allowed to stand at 25° C. and a relative humidity of 50% for 30 days).

Another aspect of the present invention provides an optical member which includes the adhesive film of the present invention.

Still another aspect of the present invention provides an optical display apparatus which includes the adhesive film of the present invention.

### Advantageous Effects

The present invention provides an adhesive protective film which can be easily removed after being adhered to an optical element and can be fixed to an optical element with high reliability through a predetermined process.

The present invention provides an adhesive protective film which can be easily removed from an optical element due to having a low peel strength increase rate even after being adhered to the optical element for a long period of time.

The present invention provides an adhesive protective film which is adhered to an optical element with low peel strength to temporarily protect the optical element before light irradiation and is easily removed from the optical element without any deformation and/or damage to the optical element by selectively cutting only the unnecessary part.

The present invention provides an adhesive protective film which can be fixed to an optical element to increase the durability of the optical element due to having significantly high peel strength after light irradiation and thermal treatment compared to before light irradiation.

### DESCRIPTION OF DRAWINGS

FIG. 1 shows a diagram illustrating a specimen for measuring T-peel strength (FIG. 1A) and a diagram illustrating a measurement operation for measuring the T-peel strength of the specimen (FIG. 1B).

### BEST MODE

The present invention will be described in detail with reference to the appended exemplary embodiments so that those skilled in the art can easily practice the invention. The present invention may be implemented in various different forms and is not intended to limit the embodiments described herein.

The terminology disclosed herein is used for the purpose of describing exemplary embodiments only and is not intended to limit the present invention.

Singular expressions include plural expressions unless the context clearly indicates otherwise.

In the present specification, “(meth)acrylic” may refer to acrylic and/or methacrylic.

In the present specification, a “copolymer” may include a polymer or a resin.

In the present specification, a “glass transition temperature” may refer to a glass transition temperature (Tg) of a monomer or compound to be measured as measured using DSC Discovery from TA Instruments. Specifically, after the temperature of a homopolymer of a monomer or compound to be measured is raised to 180° C. at a temperature increase rate of 20° C./min, slowly lowered to −100° C., and raised to 100° C. at a temperature increase rate of 10° C./min to obtain an endothermic transition curve, the inflection point of the endothermic transition curve may be determined as a glass transition temperature.

In the present specification, “peel strength” may be a value measured at 25° C. unless specifically stated otherwise.

In the present specification, the “melting point (Tm)” described for a “long-chain alkyl group-containing monofunctional or higher compound” may refer to a melting point (Tm) measured using DSC Discovery from TA Instruments. Specifically, after the temperature of a homopolymer of a monomer to be measured is raised to 180° C. at a temperature increase rate of 20° C./min, slowly lowered to −100° C., and raised to 100° C. at a temperature increase rate of 10° C./min to obtain an endothermic transition curve, the inflection point of the endothermic transition curve may be determined as a melting point.

In the present specification, a “weight average molecular weight” may be obtained as a polystyrene-converted value through gel permeation chromatography.

When describing a numerical range in the present specification, “X to Y” refers to X or more and Y or less (X≤and ≤Y).

An adhesive film of the present invention has high peel strength stability over time before light irradiation and exhibits a significantly high peel strength increase after light irradiation and thermal treatment by having both photosensitivity and thermosensitivity. The adhesive film may be adhered to an adherend with low peel strength before light irradiation.

The adhesive film refers to an adhesive film having low peel strength (also referred to as ‘initial peel strength’) before light irradiation. The adhesive film has peel strength with respect to an adherend in an appropriate range before light irradiation, is adhered to an adherend with low peel strength to temporarily protect the adherend, and can be easily removed from the adherend without any deformation and/or damage to the adherend. Therefore, the adhesive film may be used as an adhesive protective film. This differs from a coating film for forming an adhesive film that has no peel strength before light irradiation when an adhesive film is formed of a conventional photocurable adhesive composition, and the coating film formed of a photocurable adhesive composition is not capable of performing a temporary protection function for an adherend at all.

In one specific example, the adhesive film may have an initial peel strength with respect to an adherend of more than 0 gf/inch and 100 gf/inch or less, 1, 5, 10, 15, 20, 25, 30, 35, 40, 45, 50, 55, 60, 65, 70, 75, 80, 85, 90, 95, 100 gf/inch, for example, 10 gf/inch to 100 gf/inch, 20 gf/inch to 70 gf/inch, 30 gf/inch to 70 gf/inch, or 30 gf/inch to 60 gf/inch. In the above range, the adhesive film can be easily removed from the adherend without any deformation and/or damage to the adherend. The ‘initial peel strength’ may be measured by a method to be described below.

In the present specification, an “adherend” is a plastic film and may include, for example, a polyimide (PI)-based film, a polycarbonate (PC)-based film, a polyester-based film including a polyethylene naphthalate (PEN)-based film and a polyethylene terephthalate (PET)-based film, a polyethersulfone-based film, and a polyurethane-based film.

In one specific example, the adherend may be a polyimide-based film. The “polyimide-based film” may be a polymer film that is prepared by polymerization of a polyamic acid precursor and contains an imide group and an aromatic group in the repeating unit. The polyimide-based film may be widely used as a substrate for a flexible OLED panel due to its excellent mechanical properties, and may be a polyimide-based film GF200 (SKC KOLON, thickness: 50 μm).

In one specific example, the adherend may be a part of an optical element. When adhered to an adherend, the adhesive film may be removed from the adherend without any deformation and/or damage to an optical element even after being adhered to the adherend for a long period of time, and may be fixed to the adherend with significantly high peel strength after light irradiation and thermal treatment compared to before light irradiation, thereby protecting the optical element and accordingly increasing the durability of the optical element. For example, the adherend may be the above-described plastic film or a flexible substrate including the above-described plastic film.

In one specific example, the optical element is an optical element included in a foldable, flexible, or rollable display apparatus and may be, for example, a panel for a foldable, flexible, or rollable optical display apparatus. In one specific example, the optical element may be a panel for an optical display apparatus including the above-described flexible substrate.

The adhesive film, before light irradiation, can be easily removed from an adherend without any deformation and/or damage to the adherend due to having a low peel strength increase rate even after being adhered to the adherend from a long period of time.

The adhesive film has a peel strength increase rate of 1.0 or less as measured by the following Equation 1 before light irradiation. In the above range, peel strength with respect to an adherend is low even after a long period of time of adhesion to the adherend, and thus the adhesive film can be easily removed from the adherend. For example, a peel strength increase rate of the following Equation 1 may be 0.01 to 1.0, for example, 0.01, 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1.0, for example, 0.01 to 0.5 or 0.05 to 0.3:

$$Peel strength increase rate = ( P 2 - P 1 ) / P 1 \qquad [ Equation 1 ]$$

(in Equation 1,
P1 is the peel strength (units: gf/inch) of the adhesive film with respect to an adherend after a specimen prepared by adhering the adhesive film to the adherend is allowed to stand at 25° C. and a relative humidity of 50% for 30 minutes, and
P2 is the peel strength (units: gf/inch) of the adhesive film with respect to an adherend after a specimen prepared by adhering the adhesive film to the adherend is allowed to stand at 25° C. and a relative humidity of 50% for 30 days).

In one specific example, P1 (initial peel strength) in Equation 1 may be more than 0 gf/inch and 100 gf/inch or less, for example, 10 gf/inch to 100 gf/inch, 20 gf/inch to 70 gf/inch, 30 gf/inch to 70 gf/inch, or 30 gf/inch to 60 gf/inch. In one specific example, P2 in Equation 1 is higher than P1 and may be more than 0 gf/inch and 170 gf/inch or less, for example, 10 gf/inch to 100 gf/inch or 30 gf/inch to 85 gf/inch.

The adhesive film is a peel strength-enhanced adhesive film that has significantly increased peel strength with respect to an adherend after light irradiation and thermal treatment compared to before light irradiation. Since the adhesive film has significantly high peel strength after light irradiation and thermal treatment, the adhesive film may be adhered to an adherend after light irradiation and thermal treatment to increase the durability of the adherend, thereby providing a permanently protective effect. Therefore, the adhesive film serves as both a temporary processing protective film that temporarily protects the adherend and a reinforcing protective film that permanently protects the adherend, and thus process simplification, economic efficiency, and environmental friendliness effects are all obtained. The temporary processing protective film may be a film that is temporarily adhered to an adherend to temporarily protect the adherend and then removed. The reinforcing protective film may be a film that is permanently adhered to an adherend to protect the adherend from the external environment and the like and is not removed from the adherend.

Particularly, the adhesive film has significantly increased peel strength with respect to an adherend after light irradiation and thermal treatment compared to before light irradiation. Simply irradiating the adhesive film with light may increase peel strength with respect to an adherend. However, in the present invention, peel strength with respect to an adherend is significantly increased by introducing light irradiation and thermal treatment compared to the case in which only light irradiation is introduced, which may significantly increase the durability of an adherend and an optical element including an adherend.

The adhesive film may be used as a reinforcing protective film. In one specific example, the reinforcing protective film may refer to a protective film that is laminated on at least one surface of a flexible panel to protect the flexible panel from external impacts and the like.

In one specific example, the adhesive film may have a peel strength increase rate of 10 or more as measured by the following Equation 2. In the above range, the adhesive film is adhered to an adherend, and after light irradiation and thermal treatment, adhered to the adherend with high peel strength and high reliability, and thus protective and adhesive effects on the adherend can be significantly increased.

$$Peel strength increase rate = P 3 / P 1 \qquad [ Equation 2 ]$$

(in Equation 2,
P1 is the peel strength (units: gf/inch) of the adhesive film with respect to an adherend after a specimen prepared by adhering the adhesive film to the adherend is allowed to stand at 25° C. and a relative humidity of 50% for 30 minutes, and
P3 is the peel strength (units: gf/inch) of the adhesive film with respect to an adherend after a specimen prepared by adhering the adhesive film to the adherend is allowed to stand at 25° C. and a relative humidity of 50% for 30 minutes, irradiated with light, and thermally treated)

In one specific example, the peel strength increase rate of Equation 2 may be 10 to 200, for example, 10, 20, 30, 40, 50, 60, 70, 80, 90, 100, 110, 120, 130, 140, 150, 160, 170, 180, 190, 200, for example, 10 to 50 or 10 to 20. In the above range, the initial peel strength and peel strength after light irradiation and thermal treatment of the adhesive film can be easily secured.

In Equation 2, P1 (initial peel strength) may be more than 0 gf/inch and 100 gf/inch or less, for example, 10 gf/inch to 100 gf/inch, 20 gf/inch to 70 gf/inch, or 30 gf/inch to 70 gf/inch. In the above range, the adhesive film can be easily removed from an adherend without any deformation and/or damage to an optical member, and peel strength can be easily increased after light irradiation and thermal treatment.

In Equation 2, P3 (peel strength after light irradiation and thermal treatment) may be 500 gf/inch or more, for example, 500 gf/inch to 2000 gf/inch or 500 gf/inch to 1000 gf/inch. In the above range, the adhesive film is adhered to an adherend with high peel strength and high reliability, and thus an adhesive effect on the adherend and an effect of improving the durability of the optical element can be provided.

In the present invention, P3 is a value measured after a specimen of the adhesive film and an adherend is irradiated with light and thermally treated. In the present invention, the peel strength of the adhesive film after light irradiation and thermal treatment is increased by a physical change in the adhesive film resulting from enhancing the cohesiveness and/or modulus of the adhesive film after light irradiation and thermal treatment.

The “light irradiation” may include irradiating UV energy at 1,000 mJ/cm² with a wavelength of 280 to 430 nm, for example, a wavelength of 350 to 390 nm, 380 to 390 nm, or 385 nm. UV irradiation may be performed using one or more of a UV LED, a high-pressure mercury lamp, and a metal halide lamp.

The “thermal treatment” may include standing at a constant temperature of 50° C. for 20 minutes.

In one specific example, the adhesive film may have a peel strength increase rate of 3 or more and less than 10 as measured by the following Equation 3. In the above range, the adhesive film is adhered to an adherend, and after light irradiation, is adhered to the adherend with high peel strength and high reliability, and thus protective and adhesive effects on the adherend can be significantly increased.

$$Peel strength increase rate = P 4 / P 1 \qquad [ Equation 3 ]$$

(in Equation 3,
P1 is the peel strength (units: gf/inch) of the adhesive film with respect to an adherend after a specimen prepared by adhering the adhesive film to the adherend is allowed to stand at 25° C. and a relative humidity of 50% for 30 minutes, and
P4 is the peel strength (units: gf/inch) of the adhesive film with respect to an adherend after a specimen prepared by adhering the adhesive film to the adherend is allowed to stand at 25° C. and a relative humidity of 50% for 30 minutes and irradiated with light)

For example, the peel strength increase rate of Equation 3 may be 3 to 9, 4 to 8, or 5 to 7. The “light irradiation” may include irradiating UV energy at 1,000 mJ/cm² with a wavelength of 280 to 430 nm, for example, a wavelength of 350 to 390 nm, 380 to 390 nm, or 385 nm. UV irradiation may be performed using one or more of a UV LED, a high-pressure mercury lamp, and a metal halide lamp.

The adhesive film is formed of an adhesive composition including a (meth)acrylic based copolymer, a curing agent, an aromatic group-containing monofunctional or higher compound, a long-chain alkyl group-containing monofunctional or higher compound, and an initiator.

In one specific example, the adhesive film may be a thermally cured product of an adhesive composition including a (meth)acrylic based copolymer, a curing agent, an aromatic group-containing monofunctional or higher compound, a long-chain alkyl group-containing monofunctional or higher compound, and an initiator.

In one specific example, in the adhesive film, the aromatic group-containing monofunctional or higher compound, the long-chain alkyl group-containing monofunctional or higher compound, and the initiator may be dispersed in a matrix for an adhesive film which is a thermally cured product of the (meth)acrylic based copolymer and the curing agent.

### (Meth)acrylic Based Copolymer

The (meth)acrylic based copolymer may form a matrix of the adhesive film and provide the initial peel strength of the adhesive film by being cured by a curing agent. Also, the (meth)acrylic based copolymer may also help enhance the cohesiveness of the adhesive film together with the aromatic group-containing monofunctional or higher compound and the long-chain alkyl group-containing monofunctional or higher compound after light irradiation and thermal treatment.

The (meth)acrylic based copolymer may have a glass transition temperature (Tg) of −10° C. or lower, for example, −20° C. or lower or −60° C. to −20° C. In the above range, the (meth)acrylic based copolymer can help provide wettability (close contact) to an adherend and the initial peel strength of the adhesive film. After light irradiation and thermal treatment, shrinkage of the adhesive film is suppressed by controlling the glass transition temperature of the adhesive film, and thus peel strength can be increased.

The (meth)acrylic based copolymer may have a weight average molecular weight of 500,000 g/mol or more, specifically, 600,000 to 2,500,000 g/mol. In the above range, the (meth)acrylic based copolymer can help provide wettability to an adherend and the initial peel strength of the adhesive film.

The (meth)acrylic based copolymer may include a copolymer of a monomer mixture including an alkyl group-containing (meth)acrylic based monomer and a hydroxyl group-containing (meth)acrylic based monomer.

The alkyl group-containing (meth)acrylic based monomer forms a matrix of the adhesive film and may include an unsubstituted straight-chain or branched-chain alkyl group-containing (meth)acrylic acid ester having 1 to 20 carbon atoms, for example, 1 to 10 carbon atoms or 1 to 6 carbon atoms.

For example, the alkyl group-containing (meth)acrylic based monomer may include one or more of methyl (meth)acrylate, ethyl (meth)acrylate, propyl (meth)acrylate, n-butyl (meth)acrylate, t-butyl (meth)acrylate, isobutyl (meth)acrylate, pentyl (meth)acrylate, hexyl (meth)acrylate, heptyl (meth)acrylate, ethylhexyl (meth)acrylate, octyl (meth)acrylate, isooctyl (meth)acrylate, nonyl (meth)acrylate, decyl (meth)acrylate, and lauryl (meth)acrylate.

The alkyl group-containing (meth)acrylic based monomer may be included in an amount of 85 mol % to 99.5 mol %, specifically, 90 mol % to 99 mol % or 95 mol % to 98 mol % in the monomer mixture. In the above range, it can be effective in providing wettability to an adherend and the initial peel strength of the adhesive film.

The hydroxyl group-containing (meth)acrylic based monomer may be a (meth)acrylate containing one or more hydroxyl groups. For example, the hydroxyl group-containing (meth)acrylate may include an alkyl group-containing (meth)acrylic acid ester that is substituted with one or more hydroxyl groups and has 1 to 20 carbon atoms, specifically, 2 to 11 carbon atoms. For example, the hydroxyl group-containing (meth)acrylic based monomer may be one or more of 2-hydroxyethyl (meth)acrylate, 3-hydroxypropyl (meth)acrylate, 4-hydroxybutyl (meth)acrylate, hydroxyhexyl (meth)acrylate, 1,4-cyclohexanedimethanol mono(meth)acrylate, 1-chloro-2-hydroxypropyl (meth)acrylate, diethylene glycol mono(meth)acrylate, 1,6-hexanediol mono(meth)acrylate, pentaerythritol tri(meth)acrylate, dipentaerythritol penta(meth)acrylate, neopentyl glycol mono(meth)acrylate, trimethylolpropane di(meth)acrylate, trimethylolethane di(meth)acrylate, 2-hydroxy-3-phenyloxypropyl(meth)acrylate, 4-hydroxycyclopentyl (meth)acrylate, 4-hydroxycyclohexyl(meth)acrylate, and cyclohexanedimethanol mono(meth)acrylate.

The hydroxyl group-containing (meth)acrylic based monomer may be included in an amount of 0.1 mol % to 15 mol %, specifically, 0.5 mol % to 15 mol %, 0.5 mol % to 5 mol %, 2 mol % to 10 mol %, or 1 mol % to 5 mol % in the monomer mixture. In the above range, it can be effective in imparting cohesiveness to the adhesive film and providing the initial peel strength of the adhesive film.

The monomer mixture may further include a carboxylic acid group-containing monomer. The carboxylic acid group-containing monomer may help provide initial adhesive strength by increasing the glass transition temperature of the (meth)acrylic based copolymer. The carboxylic acid group-containing monomer may include (meth)acrylic acid, but the present invention is not limited thereto.

The carboxylic acid group-containing monomer may be included in an amount of 0 to 5 mol %, specifically, 0.05 mol % to 5 mol % or 0.1 mol % to 5 mol % in the monomer mixture. In the above range, it can be effective in imparting cohesiveness to the adhesive film and providing the initial peel strength of the adhesive film.

The monomer mixture may include a (meth)acrylic based monomer whose homopolymer has a glass transition temperature of −80° C. or higher and 0° C. or lower, specifically, −60° C. to −20° C. In the above range, it can be easy to prepare a (meth)acrylic based copolymer having the above-described glass transition temperature range.

The monomer mixture may include methyl acrylate, acrylic acid, methacrylic acid, or the like, but the present invention is not limited thereto.

In one specific example, the monomer mixture may not include an aromatic group-containing monomer. The (meth)acrylic based copolymer may be a non-aromatic (meth)acrylic copolymer. It may be difficult for an adhesive film formed of a composition including a (meth)acrylic based copolymer formed from a monomer mixture including an aromatic group-containing monomer to reach the above-described peel strength increase rate of Equation 2.

In one specific example, the alkyl group-containing (meth)acrylic based monomer, the hydroxyl group-containing (meth)acrylic based monomer, and the carboxylic acid group-containing monomer may be included in the total amount of 95 mol % or more, for example, 95 to 100 mol % or 100 mol % in the monomer mixture. In the above range, the effects of the present invention can be easily implemented.

The (meth)acrylic based copolymer may be prepared by polymerizing the monomer mixture using a typical polymerization method. The polymerization method may include a typical method known to those skilled in the art. For example, the (meth)acrylic based copolymer may be prepared by adding an initiator to the monomer mixture and then subjecting the resulting mixture to a typical copolymerization method, for example, suspension polymerization, emulsion polymerization, solution polymerization, or the like. The polymerization temperature may be 60° C. to 70° C., and the polymerization time may be 4 hours to 8 hours. As the initiator, a typical initiator including an azo-based polymerization initiator; and/or a peroxide such as benzoyl peroxide or acetyl peroxide may be used.

### Curing Agent

The curing agent may help thermally cure the (meth)acrylic based copolymer to form a matrix of the adhesive film and provide the initial peel strength of the adhesive film.

The curing agent is a thermal curing agent and may include one or more of an isocyanate-based curing agent, a metal chelate-based curing agent, a carbodiimide-based curing agent, an aziridine-based curing agent, and an epoxy-based curing agent.

In one specific example, the curing agent may include an isocyanate-based curing agent alone or a mixture of an isocyanate-based curing agent and a metal chelate-based curing agent. The above-described mixture may more easily implement the effects of the present invention. For example, the mixture of the isocyanate-based curing agent and the metal chelate-based curing agent may be included.

The isocyanate-based curing agent may include a bifunctional or higher isocyanate-based curing agent, specifically, a bifunctional to hexafunctional isocyanate-based curing agent. In one specific embodiment, the isocyanate-based curing agent may include one or more of xylene diisocyanate (XDI) including m-xylene diisocyanate and the like, methylene bis(phenyl isocyanate) (MDI) including 4,4′-methylene bis(phenyl isocyanate) and the like, naphthalene diisocyanate, tolylene diisocyanate, hexamethylene diisocyanate, and isophorone diisocyanate, or an adduct thereof. For example, the adduct may be a trimethylolpropane adduct of tolylene diisocyanate, a trimethylolpropane adduct of hexamethylene diisocyanate, a trimethylolpropane adduct of isophorone diisocyanate, a trimethylolpropane adduct of xylene diisocyanate, an isocyanurate adduct of tolylene diisocyanate, an isocyanurate adduct of hexamethylene diisocyanate, or an isocyanurate adduct of isophorone diisocyanate. As the isocyanate-based curing agent, one or more of those listed above may be included.

The isocyanate-based curing agent may be included in an amount of 5 parts by weight or less, for example, 0.001 to 3 parts by weight or 0.01 to 2 parts by weight with respect to 100 parts by weight of the (meth)acrylic based copolymer. In the above range, the reliability of the adhesive film can increase. Preferably, the isocyanate-based curing agent may be included in an amount of 0.3 to 2 parts by weight with respect to 100 parts by weight of the (meth)acrylic based copolymer. In the above range, the reliability of the adhesive film can increase, and the effects of the present invention can be easily implemented.

As the metal chelate-based curing agent, a typical metal chelate-based curing agent may be used. For example, the metal chelate-based curing agent may include a curing agent including a metal such as aluminum, titan, iron, copper, zinc, tin, titanium, nickel, antimony, magnesium, vanadium, chromium, zirconium, or the like. For example, the metal chelate-based curing agent may include one or more of aluminum ethylacetoacetate diisopropylate, aluminum tris(ethyl acetoacetate), alkylacetoacetate aluminum diisopropylate, aluminum isopropylate, mono-sec-butoxyaluminum diisopropylate, aluminum-sec-butyrate, aluminum ethylate, tetraisopropyl titanate, tetra-n-butyl titanate, a butyl titanate dimer, titanium acetylacetonate, titanium octylene glycolate, titanium tetraacetylacetonate, titanium ethylacetoacetate, polyhydroxy titanium stearate, and aluminum acetylacetonate.

The metal chelate-based curing agent may be included in an amount of 3 parts by weight or less, for example, 0.001 to 1 part by weight or 0.01 to 1 part by weight with respect to 100 parts by weight of the (meth)acrylic based copolymer. In the above range, additional effects can be obtained without affecting the effects of the adhesive film according to the present invention. Preferably, the metal chelate-based curing agent may be included in an amount of 0.2 to 1 part by weight with respect to 100 parts by weight of the (meth)acrylic based copolymer. In the above range, the reliability of the adhesive film can increase, and the effects of the present invention can be easily implemented.

The curing agent may be included in an amount of 0.01 to 8 parts by weight, for example, 0.01 to 3 parts by weight or 0.5 to 3 parts by weight with respect to 100 parts by weight of the (meth)acrylic based copolymer. In the above range, the reliability of the adhesive film can increase. In one specific example, the curing agent may be included in an amount of 0.5 to 3 parts by weight with respect to 100 parts by weight of the (meth)acrylic based copolymer. In the above range, the effects of the adhesive film according to the present invention can be easily implemented.

### Aromatic Group-Containing Monofunctional or Higher Compound

The aromatic group-containing monofunctional or higher compound has one or more functional groups that can react (e.g., can be cured) with an initiator. The “functional group” may refer to a vinyl group or a (meth)acrylate group. In one specific example, the aromatic group-containing monofunctional or higher compound may be an aromatic group-containing monofunctional or higher UV-reactive compound.

The aromatic group-containing monofunctional or higher compound may increase the cohesiveness of the adhesive film after light irradiation. Therefore, when the adhesive film is cured with light while being adhered to the surface of an adherend, the adhesive film is adhered to the adherend with higher peel strength, and thus the peel strength of the adhesive film may increase.

The aromatic group-containing monofunctional or higher compound may increase peel strength by a physical change in the adhesive film through light irradiation by having photosensitivity.

The aromatic group-containing monofunctional or higher compound is an aromatic group-containing monofunctional or higher monomer, and it may be preferable that the glass transition temperature of the homopolymer of the monomer has a predetermined range compared to the glass transition temperature of the (meth)acrylic based copolymer. Accordingly, even when the adhesive film is cured by light irradiation, shrinkage of the adhesive film may be suppressed, thereby increasing the peel strength after light irradiation.

In one specific example, the glass transition temperature of the homopolymer of the aromatic group-containing monofunctional or higher compound is higher than the glass transition temperature of the (meth)acrylic based copolymer, and the difference therebetween may preferably be 20° C. or higher, for example, 20° C. to 120° C. or 40° C. to 100° C. In the above range, an increase in peel strength after light irradiation can be expected.

The aromatic group-containing monofunctional or higher compound may have a homopolymer glass transition temperature of 0° C. or higher, for example, 0° C. to 50° C. or 5° C. to 50° C. In the above range, the glass transition temperature is higher than that of the (meth)acrylic based copolymer, and thus it is possible to obtain an effect of enhancing the peel strength of the adhesive film by enhancing the cohesiveness after light irradiation.

The aromatic group-containing monofunctional or higher compound may have one or more aromatic groups. A UV-reactive compound having one or more aromatic groups may increase a peel strength increase rate of Equation 2.

The aromatic group-containing monofunctional or higher compound may include a compound of the following Chemical Formula 1, but the present invention is not limited thereto:

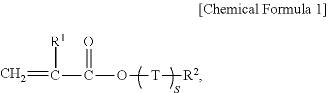

(in Chemical Formula 1,
R¹ is hydrogen or a methyl group,
s is an integer from 0 to 10,
R² is a substituted or unsubstituted C6 to C50 aryl group or a substituted or unsubstituted C6 to C50 aryloxy group, and
T is a substituted or unsubstituted C1 to C6 alkylene group or a substituted or unsubstituted C1 to C6 alkyleneoxy group).

In the present specification, “substituted” in “substituted or unsubstituted” means that one or more hydrogen atoms are substituted with a C1 to C10 alkyl group, a C1 to C10 thioalkyl group, a C1 to C10 alkoxy group, a halogen (F, Cl, Br, or I), a C3 to C10 cycloalkyl group, or a C6 to C20 aryl group.

Specifically, R² may be a substituted or unsubstituted phenoxy group, benzyl group, phenyl group, biphenyl group, terphenyl group, or naphthyl group. Specifically, the aromatic group-containing monofunctional or higher compound may include one or more of phenoxy (meth)acrylate, 2-ethylphenoxy (meth)acrylate, 2-phenoxyethyl (meth)acrylate (ethylene glycol phenyl ether (meth)acrylate), benzyl (meth)acrylate, phenyl (meth)acrylate, 2-ethylthiophenyl (meth)acrylate, 2-phenylethyl (meth)acrylate, 3-phenylpropyl (meth)acrylate, 4-phenylbutyl (meth)acrylate, 2-(2-methylphenyl)ethyl (meth)acrylate, 2-(3-methylphenyl)ethyl (meth)acrylate, 2-(4-methylphenyl)ethyl (meth)acrylate, 2-(4-propylphenyl)ethyl (meth)acrylate, 2-(4-(1-methylethyl)phenyl)ethyl (meth)acrylate, 2-(4-methoxyphenyl)ethyl (meth)acrylate, 2-(4-cyclohexylphenyl)ethyl (meth)acrylate, 2-(2-chlorophenyl)ethyl (meth)acrylate, 2-(3-chlorophenyl)ethyl (meth)acrylate, 2-(4-chlorophenyl)ethyl (meth)acrylate, 2-(4-bromophenyl)ethyl (meth)acrylate, 2-(3-phenylphenyl)ethyl (meth)acrylate, o-biphenyl (meth)acrylate, m-biphenyl (meth)acrylate, p-biphenyl (meth)acrylate, 2,6-terphenyl (meth)acrylate, o-terphenyl (meth)acrylate, m-terphenyl (meth)acrylate, p-terphenyl (meth)acrylate, 4-(4-methylphenyl)phenyl (meth)acrylate, 4-(2-methylphenyl)phenyl (meth)acrylate, 2-(4-methylphenyl)phenyl (meth)acrylate, 2-(2-methylphenyl)phenyl (meth)acrylate, 4-(4-ethylphenyl)phenyl (meth)acrylate, 4-(2-ethylphenyl)phenyl (meth)acrylate, 2-(4-ethylphenyl)phenyl (meth)acrylate, and 2-(2-ethylphenyl)phenyl (meth)acrylate, which may be included alone or in combination of two or more.

In one specific example, the aromatic group-containing monofunctional or higher compound may include one or more of benzyl (meth)acrylate, ethylene glycol phenyl ether (meth)acrylate, phenylbenzyl (meth)acrylate, ethoxylated phenyl (meth)acrylate including ethoxylated phenyl acrylate (particularly, phenyl(EO) 1 acrylate and phenyl(EO) 2 acrylate) and the like, ethoxylated phenylphenol (meth)acrylate including ethoxylated phenylphenol acrylate (o-phenylphenol(EO) acrylate) and the like, phenoxybenzyl (meth)acrylate including phenoxybenzyl acrylate and the like, biphenylmethyl (meth)acrylate including biphenylmethyl acrylate and the like, and naphthyl (meth)acrylate including 1-naphthyl acrylate and the like.

The aromatic group-containing monofunctional or higher compound may be included in an amount of 1 to 25 parts by weight, for example, 1 to 20 parts by weight or 5 to 20 parts by weight with respect to 100 parts by weight of the (meth)acrylic based copolymer. In the above range, it can contribute to increasing the peel strength of the adhesive film after light irradiation.

### Long-Chain Alkyl Group-Containing Monofunctional or Higher Compound

The long-chain alkyl group-containing monofunctional or higher compound may increase peel strength by a physical change in the adhesive film through light irradiation by having photosensitivity. The long-chain alkyl group-containing monofunctional or higher compound may maximize an increase in peel strength through thermal treatment by having thermosensitivity unlike the aromatic group-containing monofunctional or higher compound. In other words, the long-chain alkyl group-containing monofunctional or higher compound does not have an inherent melting point. However, the long-chain alkyl group-containing monofunctional or higher compound is converted into a polymer form through light irradiation, and accordingly, it has a melting point in a predetermined range. As a long-chain alkyl group is crystallized at a temperature below the melting point, the adhesive film provides low peel strength, but when the adhesive film is thermally treated at a temperature above the melting point while being adhered to an adherend, the long-chain alkyl group may provide fluidity, thereby increasing peel strength. In one specific example, the melting point may be 30 to 60° C., for example, 30 to 50° C. or 40 to 50° C. In the above range, the effects of the present invention can be easily implemented. Here, “light irradiation” may be performed under the same conditions as described above.

In addition, the long-chain alkyl group-containing monofunctional or higher compound provides thermal stability to the adhesive film by having a long-chain alkyl group, which may help lower the peel strength increase rate of Equation 1.

The long-chain alkyl group-containing monofunctional or higher compound has one or more functional groups that can react (e.g., can be cured) with an initiator. The “functional group” may refer to a vinyl group or a (meth)acrylate group. In one specific example, the long-chain alkyl group-containing monofunctional or higher compound may be a long-chain alkyl group-containing monofunctional UV-reactive monomer.

In one specific example, the long-chain alkyl group-containing monofunctional or higher compound may be a non-aromatic compound not containing an aromatic group.

As the long-chain alkyl group-containing monofunctional or higher compound, a compound that provides the above-described melting point after light irradiation may be selected and used. For example, the long-chain alkyl group-containing monofunctional or higher compound may be long-chain alkyl group-containing (meth)acrylate, and here, the long-chain alkyl group may be an unsubstituted straight-chain or branched-chain alkyl group having 12 or more carbon atoms, for example, 12, 13, 14, 15, 16, 17, 18, 19, 20, 21, 22, 23, 24, 25, 26, 27, 28, 29, 30 carbon atoms, for example, 12 to 30 carbon atoms or 12 to 28 carbon atoms. Here, the “number of carbon atoms” refers to the number of carbon atoms constituting the main chain in the ester part of the (meth)acrylate.

For example, the long-chain alkyl group-containing monofunctional or higher compound may include one or more of stearyl (meth)acrylate, behenyl (meth)acrylate, and cetyl (meth)acrylate.

The long-chain alkyl group-containing monofunctional or higher compound may be included in an amount of 1 to 50 parts by weight, for example, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50 parts by weight, for example, 1 to 10 parts by weight or 1 to 5 parts by weight with respect to 100 parts by weight of the (meth)acrylic based copolymer. In the above range, it can contribute to increasing the peel strength of the adhesive film after thermal treatment.

### Initiator

The initiator may provide a physical change in the adhesive film through light irradiation by curing the aromatic group-containing monofunctional or higher compound. The initiator includes one or more of a photoradical initiator and a cationic photoinitiator and may further include a thermal initiator.

In one specific embodiment, the initiator may include a photoinitiator having a maximum absorption wavelength within the irradiation wavelength range applied during the above-described light irradiation. For example, the initiator may have a maximum absorption wavelength in a wavelength range of 280 nm to 430 nm. In the above range, an effect of photocuring the aromatic group-containing monofunctional or higher compound by light irradiation can be obtained. Specifically, the photoinitiator may include a phosphorus-based initiator, a ketone-based initiator, or the like, but the present invention is not limited thereto.

The initiator may be included in an amount of 0.01 parts by weight to 7.5 parts by weight, for example, 0.03 parts by weight to 4.5 parts by weight or 0.1 to 1 part by weight with respect to 100 parts by weight of the (meth)acrylic based copolymer. In the above range, an effect of uniformly curing the aromatic group-containing monofunctional or higher compound by light irradiation and an effect of preventing a decrease in transparency of the adhesive film due to a residual initiator can be provided.

The adhesive composition may further include a curing accelerator.

The curing accelerator may help the curing reaction of the adhesive film to further increase the cohesiveness of an adhesive layer. The curing accelerator may include a typical curing accelerator known to those skilled in the art. Examples thereof include a tin-based metal compound, a zinc-based metal compound, an amine compound, a titanium-based metal compound, a bismuth-based metal compound, and an aluminum-based metal compound. Among them, the tin-based metal compound is preferably used. Examples thereof include tetravalent or divalent organotin-based compounds such as dibutyltin dilaurate, bis-acetylacetonate-dibutyltin, dibutyltin dimaleate, tin dimaleate, and the like, but the present invention is not limited thereto.

The curing accelerator may be included in an amount of 0.001 parts by weight to 3 parts by weight with respect to 100 parts by weight of the (meth)acrylic based copolymer. In the above range, the curing accelerator can help increase the curing speed of the adhesive film and enhance the cohesiveness.

The adhesive composition may further include a silane coupling agent.

The silane coupling agent may further increase the peel strength of the adhesive film. The silane coupling agent may include a typical silane coupling agent known to those skilled in the art. For example, the silane coupling agent may include an epoxy group-containing silane coupling agent such as glycidoxypropyltrimethoxysilane, glycidoxypropylmethyldimethoxysilane, or the like, but the present invention is not limited thereto.

The silane coupling agent may be included in an amount of 0.01 parts by weight to 5 parts by weight with respect to 100 parts by weight of the (meth)acrylic based copolymer. In the above range, the peel strength-improving effect can be further provided.

The adhesive composition may further include an additive. The additive may include a typical additive that is included in an adhesive film and known to those skilled in the art. For example, the additive may include one or more of a pigment, an ultraviolet absorber, an antioxidant, a leveling agent, an antistatic agent, a retardant, a catalyst, and a reworking agent, but the present invention is not limited thereto.

The adhesive composition may further include a solvent. The solvent may increase the coatability of the adhesive composition to provide an adhesive film that is thin and has a uniform surface. The solvent may include a typical type known to those skilled in the art. For example, the solvent may include methyl ethyl ketone, methyl isobutyl ketone, ethyl acetate, toluene, or the like, but the present invention is not limited thereto. In one specific embodiment, the adhesive composition may include the solvent in an amount of 15 wt % to 40 wt %, specifically, 20 wt % to 30 wt % based on a solid content of the adhesive film. In the above range, the composition can have excellent coatability.

The adhesive film may have a haze of 5% or less, specifically, 0.1% to 2%, and a total light transmittance of 80% or more, specifically, 85% to 95% in the visible light region (e.g., a wavelength range of 380 nm to 780 nm). In the above range, the adhesive film can be used in an optical display apparatus due to having good optical transparency.

The adhesive film may have a thickness of 200 μm or less, specifically more than 0 μm and 100 μm or less, and more specifically 5 μm to 50 μm. In the above range, the adhesive film can help provide a protective effect on a flexible panel.

The adhesive film may be manufactured by applying the adhesive composition onto one surface of a release film and performing drying and then aging (or thermal curing). The drying may be performed at 50° C. to 100° C. for 1 minute to 30 minutes. The aging (or thermal curing) may be performed at 30° C. to 70° C. for 1 day to 10 days.

An optical member according to another aspect of the present invention includes the adhesive film according to the present invention.

In one specific example, the optical member includes an optical element and an adhesive film laminated on at least one surface of the optical element, and the adhesive film may include the adhesive film according to one aspect of the present invention.

In one specific example, the optical member may include an optical element, in which an adherend is laminated on the lowermost surface thereof, and the adhesive film according to one aspect of the present invention laminated on the lower surface of the adherend.

The optical element is an optical element included in a foldable, flexible, or rollable display apparatus and may be, for example, a panel for a foldable, flexible, or rollable optical display apparatus.

The panel for an optical display apparatus may include a flexible substrate. The flexible substrate may serve to support an optical element such as an organic light-emitting diode and the like. The flexible substrate is a plastic film and may include, for example, a polyimide-based film, a polyester-based film including a polyethylene terephthalate-based film and a polyethylene naphthalate-based film, a polycarbonate-based film, and a polyethersulfone-based film.

The optical element may be laminated on the upper surface of the flexible substrate and further include a basic element for an optical display apparatus, which provides certain optical functions of the optical display apparatus, such as light emission, polarization, optical compensation, display image quality improvement, and/or conductivity. The basic element for an optical display apparatus may include an OLED element, a window film, a window, a polarizing plate, a color filter, a phase difference film, an elliptically polarizing film, a reflective polarizing film, an anti-reflection film, a compensation film, a brightness-enhancing film, an alignment film, a light diffusion film, a glass scattering prevention film, a surface protection film, an OLED element barrier layer, a plastic LCD substrate, and a transparent electrode film including indium tin oxide (ITO), fluorinated tin oxide (FTO), aluminum-doped zinc oxide (AZO), carbon nanotubes (CNTs), Ag nanowires, graphene, and the like.

The optical element may further include a protective layer laminated on the lower surface of the flexible substrate.

The protective layer is not particularly limited as long as it is optically transparent and is capable of providing flexibility. For example, the protective layer may include a protective film such as a polyester-based film including a polyethylene terephthalate-based film and a polyethylene naphthalate-based film, a polycarbonate-based film, and a polyethersulfone-based film.

In one specific example, the optical member may include a panel for an optical display apparatus including a flexible substrate, the adhesive film laminated on a lower surface of the flexible substrate, and a protective layer laminated on a lower surface of the adhesive film.

The optical member may be manufactured by changing a typical method known to those in the art. For example, the optical member may be manufactured by preparing a flexible panel including a flexible substrate, bonding a laminate of an adhesive film and a protective layer to the lower surface of the flexible substrate, and when there are no defects such as an abnormal appearance or foreign matter on the flexible substrate or the flexible panel, subjecting the resulting laminate to the above-described light irradiation so that the laminate of the adhesive film and the protective layer is bonded to the flexible panel with high peel strength. However, when there is a defect, the laminate of the adhesive film and the protective layer is peeled off of the flexible panel.

An optical display apparatus according to still another aspect of the present invention includes the adhesive film according to the present invention.

The optical display apparatus may include an organic light-emitting element display apparatus, a liquid crystal display apparatus, and the like. The optical display apparatus may include a flexible display apparatus. However, the optical display apparatus may also include a non-flexible display apparatus. \

### MODES OF THE INVENTION

Hereinafter, the configuration and operation of the present invention will be described in more detail through preferred examples of the present invention. However, it should be understood that these examples are presented as preferred examples of the present invention and are not construed as limiting the present invention in any way.

### Preparation Example 1

An ethyl acetate solvent was input into a 1 L reactor equipped with a cooling device for refluxing nitrogen gas and easily controlling the temperature. 100 parts by weight of a monomer mixture including 85 mol % of n-butyl acrylate (n-BA), 10 mol % of methyl acrylate (MA), 4 mol % of 4-hydroxybutyl acrylate (4HBA), and 1 mol % of acrylic acid (AA) was input into the reactor. Nitrogen gas was input to the monomer mixture for 30 minutes to remove oxygen, and then the internal temperature of the reactor was maintained at 62° C. The monomer mixture was uniformly stirred, and 0.07 parts by weight of azobisisobutyronitrile (AIBN) as an initiator was added and allowed to react at 62° C. for 8 hours to prepare a (meth)acrylic based copolymer (glass transition temperature: −50° C., weight average molecular weight: 1,191,000 g/mol). An ethyl acetate solvent was added to prepare a (meth)acrylic based copolymer solution (solid content: 25 wt %).

### Preparation Example 2

A toluene solvent was input into a 1 L reactor equipped with a cooling device for refluxing nitrogen gas and easily controlling the temperature. 100 parts by weight of a monomer mixture including 95 mol % of stearyl methacrylate and 5 mol % of t-butyl acrylate was input into the reactor. Nitrogen gas was input to the monomer mixture for 30 minutes to remove oxygen, and then the internal temperature of the reactor was maintained at 76° C. The monomer mixture was uniformly stirred, and 0.2 parts by weight of AIBN as an initiator was added and allowed to react at 76° C. for 4 hours to prepare a (meth)acrylic based oligomer. A toluene solvent was added to prepare a (meth)acrylic based oligomer solution (solid content: 30 wt %).

### Example 1

Based on solid content, 100 parts by weight of the (meth)acrylic based copolymer prepared in Preparation Example 1, 0.7 parts by weight of TD-75 (an isocyanate-based curing agent, Soken) and 0.5 parts by weight of Hardener M-2 (an aluminum chelate-based curing agent, Saiden) as curing agents, 15 parts by weight of benzyl acrylate (Miwon Specialty Chemical Co., Ltd.) as an aromatic group-containing monomer, 3 parts by weight of stearyl methacrylate (Sigma-Aldrich) as a long-chain alkyl group-containing monomer, and 0.4 parts by weight of Irgacure TPO (a phosphorus-based photoinitiator, BASF) as a photoinitiator were mixed, and methyl ethyl ketone was added to dilute the mixture, thereby preparing an adhesive composition (solid content: 25 wt %).

The prepared adhesive composition was applied onto the coated surface of a polyethylene terephthalate (PET) film (SKC, thickness: 75 μm, one surface coated to prevent static electricity) as a substrate film to a thickness of 13 μm and then dried at 90° C. for 4 minutes. Afterward, a release film (thickness: 25 μm, one surface release-treated with silicone) was bonded to the obtained adhesive layer and allowed to stand at 50° C. for 2 days to manufacture an adhesive film-containing sheet in which the adhesive film (thickness: 13 μm) and the release film were sequentially laminated on the substrate film.

### Examples 2 to 4

Adhesive film-containing sheets were manufactured in the same manner as in Example 1, except that the type and/or content of each component were/was changed as shown in Table 1 below. In Table 1 below, ‘-’ means that the corresponding component is not included.

### Comparative Examples 1 to 5

Adhesive film-containing sheets were manufactured in the same manner as in Example 1, except that the type and/or content of each component were/was changed as shown in Table 1 below.

### Comparative Example 6

An adhesive film-containing sheet was manufactured in the same manner as in Example 1, except that the type and/or content of each component were changed as shown in Table 1 below.

Hereinafter, the components used in the examples and comparative examples in Table 1 below are as follows.
Compound A: Benzyl acrylate
Compound B: Ethylene glycol phenyl ether acrylate
Compound C: Stearyl methacrylate
Compound D: Behenyl acrylate
Compound E: (Meth)acrylic based oligomer prepared in Preparation Example 2

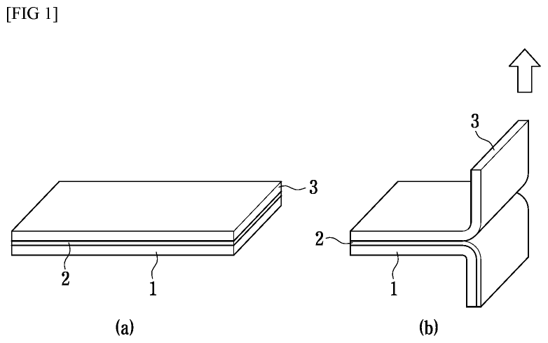

The adhesive film-containing sheets manufactured in the examples and comparative examples were evaluated for their physical properties shown in Table 1 below, and results thereof are shown in Table 1 below.
(1) Initial peel strength (units: gf/inch): The release film was peeled off of each adhesive film-containing sheet manufactured in the examples and comparative examples at 23° C. and a relative humidity of 50% to expose the adhesive film. A polyimide-based film (GF200, SKC KOLON, thickness: 50 μm) was adhered to the exposed adhesive film surface, pressed using a 2 kg roll, and cut to a size of 25 mm×100 mm (width×length) to manufacture a specimen. The manufactured specimen was allowed to stand at 25° C. and a relative humidity of 50% for 30 minutes. The resulting specimen is shown in FIG. 1A. Referring to FIG. 1A, the PET film 1, the adhesive film 2, and the polyimide-based film 3 were sequentially laminated. The peel strength when the polyimide-based film was peeled off of the adhesive film was measured by a T-peel strength measurement method at a peel temperature of 25° C., a peel speed of 2400 mm/min, and a peel angle of 180° using a tensile tester (Texture Analyzer, TA Instruments) according to JISZ2037. The measured peel strength is based on a state before UV irradiation or before long-term adhesion to an adherend and is referred to as initial peel strength.

The T-peel strength may be measured with reference to FIG. 1B. The T-peel strength is the peel strength when the polyimide-based film 3 is peeled off of the PET film 1 and the adhesive film 2. The T-peel strength may be measured by pulling and peeling the polyimide-based film 3 in the direction of the arrow shown in FIG. 1B while fixing the PET film 1 and the adhesive film 2 to the jig of TA Instruments.
(2) Peel strength after 30 days (units: gf/inch): The release film was peeled off of each adhesive film-containing sheet of the examples and comparative examples at 23° C. and a relative humidity of 50% to expose the adhesive film. A polyimide-based film (GF200, SKC KOLON, thickness: 50 μm) was adhered to the exposed adhesive film surface, pressed using a 2 kg roll, and cut to a size of 25 mm×100 mm (width×length) to manufacture a specimen. The manufactured specimen was allowed to stand at 25° C. and a relative humidity of 50% for 30 days. The peel strength when the polyimide-based film was peeled off of the adhesive film was measured in the same manner as in (1).
(3) Peel strength after UV irradiation (units: gf/inch): A specimen in which the PET film, the adhesive film, and the polyimide-based film were sequentially laminated was manufactured in the same manner as in (1). The manufactured specimen was allowed to stand at 23° C. and a relative humidity of 50% for 30 minutes. On the PET film side, the specimen was irradiated with UV energy at 1000 mJ/cm² with a wavelength of 385 nm using a UV LED irradiator (SUV-L5160A, UVSMT) and allowed to stand at 23=1° C. and a relative humidity of 55±5% for 30 minutes. The peel strength when the polyimide-based film was peeled off of the adhesive film was measured in the same manner as in (1) by a T-peel strength measurement method at a peel temperature of 25° C., a peel speed of 2400 mm/min, and a peel angle of 180° using a tensile tester (Texture Analyzer, TA Instruments) according to JISZ2037.
(4) Peel strength after UV irradiation and thermal treatment (units: gf/inch): A specimen in which the PET film, the adhesive film, and the polyimide-based film were sequentially laminated was manufactured in the same manner as in (1). On the PET film side, the manufactured specimen was irradiated with UV energy at 1000 mJ/cm² with a wavelength of 385 nm using a UV LED irradiator (SUV-L5160A, UVSMT). Then, the resulting specimen was allowed to stand in an oven set to 50° C. for 20 minutes. The specimen was taken out of the oven and then allowed to stand at 23° C. and a relative humidity of 50% for 30 minutes. The peel strength when the polyimide-based film was peeled off of the adhesive film was measured in the same manner as in (1) by a T-peel strength measurement method at a peel temperature of 25° C., a peel speed of 2400 mm/min, and a peel angle of 180° using a tensile tester (Texture Analyzer, TA Instruments) according to JISZ2037.

TABLE 1

| | Examples | | | | Comparative Examples | | | | | |
|---|---|---|---|---|---|---|---|---|---|---|
| | 1 | 2 | 3 | 4 | 1 | 2 | 3 | 4 | 5 | 6 |
| Compound | 15 | — | 15 | — | 15 | — | 15 | — | — | 30 |
| A | | | | | | | | | | |
| Compound | — | 15 | — | 15 | — | 15 | — | 15 | — | — |
| B | | | | | | | | | | |
| Compound | 3 | 3 | — | — | — | — | — | — | 5 | — |
| C | | | | | | | | | | |
| Compound | — | — | 3 | 3 | — | — | — | — | — | — |
| D | | | | | | | | | | |
| Compound | — | — | — | — | — | — | 3 | 3 | — | — |
| E | | | | | | | | | | |
| Initial peel | 40 | 36 | 39 | 38 | 42 | 40 | 41 | 39 | 92 | 40 |
| strength | | | | | | | | | | |
| Peel | 45 | 43 | 44 | 47 | 46 | 43 | 92 | 88 | 163 | 45 |
| strength | | | | | | | | | | |
| after 30 | | | | | | | | | | |
| days | | | | | | | | | | |
| Peel | 0.125 | 0.194 | 0.128 | 0.237 | 0.095 | 0.075 | 1.244 | 1.256 | 0.772 | 0.125 |
| strength | | | | | | | | | | |
| increase | | | | | | | | | | |
| rate after 30 | | | | | | | | | | |
| days of | | | | | | | | | | |
| Equation 1 | | | | | | | | | | |
| Peel | 291 | 312 | 286 | 299 | 294 | 309 | 286 | 302 | 119 | 324 |
| strength | | | | | | | | | | |
| after UV | | | | | | | | | | |
| irradiation | | | | | | | | | | |
| Peel | 7.275 | 8.667 | 7.333 | 7.868 | 7 | 7.725 | 6.976 | 7.744 | 1.293 | 8.1 |
| strength | | | | | | | | | | |
| increase | | | | | | | | | | |
| rate after | | | | | | | | | | |
| UV | | | | | | | | | | |
| irradiation | | | | | | | | | | |
| of Equation | | | | | | | | | | |
| 3 | | | | | | | | | | |
| Peel | 578 | 629 | 596 | 610 | 342 | 334 | 569 | 593 | 295 | 345 |
| strength | | | | | | | | | | |
| after UV | | | | | | | | | | |
| irradiation | | | | | | | | | | |
| and thermal | | | | | | | | | | |
| treatment | | | | | | | | | | |
| Peel | 14.45 | 17.472 | 15.282 | 16.053 | 8.143 | 8.35 | 13.878 | 15.205 | 3.207 | 8.625 |
| strength | | | | | | | | | | |
| increase | | | | | | | | | | |
| rate after | | | | | | | | | | |
| UV | | | | | | | | | | |
| irradiation | | | | | | | | | | |
| and thermal | | | | | | | | | | |
| treatment of | | | | | | | | | | |
| Equation 2 | | | | | | | | | | |

As shown in Table 1, the adhesive films of the present invention exhibited a low peel strength increase rate after being adhered to the adherend, was adhered to the adherend with low peel strength before light irradiation, and exhibited significantly high peel strength after light irradiation and thermal treatment compared to before light irradiation.

On the other hand, the adhesive films of the comparative examples did not satisfy all the effects of the present invention.

Simple changes and modifications of the present invention can be easily implemented by those skilled in the art, and all such changes and modifications can be considered to be included in the scope of the present invention.

1. An adhesive film comprising a thermally cured product of an adhesive composition including a (meth)acrylic based copolymer, a curing agent, an aromatic group-containing monofunctional or higher compound, a long-chain alkyl group-containing monofunctional or higher compound, and an initiator, wherein the adhesive film has a peel strength increase rate of 1.0 or less as measured by the following Equation 1 before light irradiation:
$$Peel strength increase rate = ( P 2 - P 1 ) / P 1 , \qquad [ Equation 1 ]$$
where, in Equation 1,
P1 is the peel strength (units: gf/inch) of the adhesive film with respect to an adherend after a specimen prepared by adhering the adhesive film to the adherend is allowed to stand at 23° C. and a relative humidity of 50% for 30 minutes, and
P2 is the peel strength (units: gf/inch) of the adhesive film with respect to an adherend after a specimen prepared by adhering the adhesive film to the adherend is allowed to stand at 23° C. and a relative humidity of 50% for 30 days.

2. The adhesive film of claim 1, wherein the adhesive film has a peel strength increase rate of 10 or more as measured by the following Equation 2:
$$Peel strength increase rate = P 3 / P 1 , \qquad [ Equation 2 ]$$
where, in Equation 2,
P1 is the peel strength (units: gf/inch) of the adhesive film with respect to an adherend after a specimen prepared by adhering the adhesive film to the adherend is allowed to stand at 25° C. and a relative humidity of 50% for 30 minutes, and
P3 is the peel strength (units: gf/inch) of the adhesive film with respect to an adherend after a specimen prepared by adhering the adhesive film to the adherend is allowed to stand at 25° C. and a relative humidity of 50% for 30 minutes, irradiated with light, and thermally treated.

3. The adhesive film of claim 2, wherein P3 in Equation 2 is 500 gf/inch or more.

4. The adhesive film of claim 1, wherein in the adhesive film, the aromatic group-containing monofunctional or higher compound, the long-chain alkyl group-containing monofunctional or higher compound, and the initiator are dispersed in a matrix for an adhesive film, which is a thermally cured product of the (meth)acrylic based copolymer and the curing agent.

5. The adhesive film of claim 1, wherein the long-chain alkyl group-containing monofunctional or higher compound forms a polymer having a melting point of 30 to 60° C. through light irradiation.

6. The adhesive film of claim 1, wherein the long-chain alkyl group-containing monofunctional or higher compound includes a C12 or higher straight-chain or branched-chain alkyl group-containing (meth)acrylate.

7. The adhesive film of claim 1, wherein the long-chain alkyl group-containing monofunctional or higher compound includes one or more of stearyl (meth)acrylate, behenyl (meth)acrylate, and cetyl (meth)acrylate.

8. The adhesive film of claim 1, wherein the long-chain alkyl group-containing monofunctional or higher compound is included in an amount of 1 part by weight to 50 parts by weight with respect to 100 parts by weight of the (meth)acrylic based copolymer.

9. The adhesive film of claim 1, wherein a homopolymer of the aromatic group-containing monofunctional or higher compound has a glass transition temperature higher than a glass transition temperature of the (meth)acrylic based copolymer.

10. The adhesive film of claim 9, wherein the glass transition temperature of the homopolymer of the aromatic group-containing monofunctional or higher compound and the glass transition temperature of the (meth)acrylic based copolymer differ by 20° C. or higher.

11. The adhesive film of claim 1, wherein the aromatic group-containing monofunctional or higher compound includes a compound of the following Chemical Formula 1: 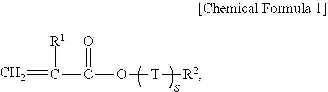
where, in Chemical Formula 1,
R¹ is hydrogen or a methyl group,
s is an integer from 0 to 10,
R² is a substituted or unsubstituted C6 to C50 aryl group or a substituted or unsubstituted C6 to C50 aryloxy group, and
T is a substituted or unsubstituted C1 to C6 alkylene group or a substituted or unsubstituted C1 to C6 alkyleneoxy group.

12. The adhesive film of claim 1, wherein the aromatic group-containing monofunctional or higher compound is included in an amount of 1 part by weight to 25 parts by weight with respect to 100 parts by weight of the (meth)acrylic based copolymer.

13. The adhesive film of claim 1, wherein the (meth)acrylic based copolymer includes a copolymer of a monomer mixture including an alkyl group-containing (meth)acrylic based monomer, a hydroxyl group-containing (meth)acrylic based monomer, and a carboxylic acid group-containing (meth)acrylic based monomer.

14. The adhesive film of claim 1, wherein the curing agent includes a mixture of an isocyanate-based curing agent and a metal chelate-based curing agent.

15. The adhesive film of claim 1, wherein the curing agent is included in an amount of 0.01 parts by weight to 8 parts by weight with respect to 100 parts by weight of the (meth)acrylic based copolymer.

16. An optical member comprising the adhesive film according to claim 1.

17. The optical member of claim 16, wherein the optical member includes a panel for an optical display apparatus including a flexible substrate, the adhesive film laminated on a lower surface of the flexible substrate, and a protective layer laminated on a lower surface of the adhesive film.

18. An optical display apparatus comprising the adhesive film according to claim 1.
